(19) United States
(12) Patent Application Publication
(10) Pub. No.: US 2023/0006310 A1
(43) Pub. Date: Jan. 5, 2023

(54) RECHARGEABLE BATTERY PACK

(71) Applicant: Robert Bosch GmbH, Stuttgart (DE)

(72) Inventors: Simon Buck, St. Johann (DE); Stephanie Gollhofer, Reutlingen (DE); Aaron Ruthardt, Hildrizhausen (DE); Balint Becsei, Budapest (HU); Simone Schramm, Tuebingen (DE); Wolf Zahn, Stuttgart (DE)

(21) Appl. No.: 17/848,539

(22) Filed: Jun. 24, 2022

(30) Foreign Application Priority Data
Jun. 30, 2021 (DE) 10 2021 206 819.7

(51) Int. Cl. H01M 50/519; H05K 1/18; H05K 3/32; H01M 50/213; H01M 50/503; B23K 31/02

(52) U.S. Cl. CPC H01M 50/519; H05K 1/181; H05K 3/328; H01M 50/213; H01M 50/503; B23K 31/02; H05K 2201/10037; H01M 2220/20

(57) ABSTRACT

A rechargeable battery pack. The rechargeable battery pack includes a housing, at least one rechargeable battery cell including a cell connector, and a circuit board. The at least one rechargeable battery cell being electrically connected to the circuit board via the cell connector. The circuit board includes a connection point for the materially bonded connection of the cell connector to the circuit board, the connection point being situated on a side of the circuit board facing away from the rechargeable battery cells.

### BACKGROUND INFORMATION

A rechargeable battery pack including a cell holder is described in German Patent Application No. DE 10 2019 213 965 A1.

### SUMMARY

The present invention relates, in particular, to a rechargeable battery pack including a housing, including a plurality of rechargeable battery cells, which are situated in the housing, including at least two individual cell receptacles, which are situated in a first main plane, including at least two individual cell receptacles, which are situated in a second main plane, including at least one individual cell receptacle, which is situated in an intermediate plane, the main planes and the intermediate plane extending in parallel to one another and through a center axis of the respective individual cell receptacles. It is provided that the individual cell receptacles are situated in such a way that a distance between the main plane and the intermediate plane is in a range between 54% and 60%, in particular, in a range between 56% and 58%, of a diameter of the rechargeable battery cells. As a result, a rechargeable battery pack having an optimal geometry may be advantageously provided for a flexible installation in a consumer.

According to an example embodiment of the present invention, the rechargeable battery pack is, in particular, part of a system, which is made up of the rechargeable battery pack and a consumer, the consumer being provided with energy during the operation via the rechargeable battery pack. The rechargeable battery pack may, for example, be designed as a hand-held power tool rechargeable battery pack or as an electric bicycle rechargeable battery pack. The rechargeable battery pack is designed, in particular, as an exchangeable rechargeable battery pack, which is preferably designed to be detachable from the consumer without tools. The rechargeable battery pack is designed, in particular, to be connectable to a charging device for charging the rechargeable battery pack. Alternatively or in addition, the rechargeable battery pack may also be designed in such a way that it is chargeable in the state connected to the consumer.

The consumer may be designed, in particular, as a gardening tool such as, for example, a lawn mower or a hedge trimmer, as a household appliance such as, for example, an electric window cleaner or hand-held vacuum cleaner, as a hand-held power tool such as, for example, an angle sander, a power screw driver, a power drill, a drill hammer, etc., as an electric means of transportation such as, for example, an electric bicycle in the form of a Pedelec or eBike, or as a measuring tool such as, for example, a laser range finder. In addition, it is also possible that the consumer is designed as a different, in particular, portable device such as, for example, a construction site lamp, a suction device or a construction site radio.

According to an example embodiment of the present invention, the housing of the rechargeable battery pack is designed preferably as an exterior housing. The rechargeable battery pack, in particular, the housing of the rechargeable battery pack, may be detachably connectable via a mechanical interface to the consumer and/or to a charging device. The housing of the rechargeable battery pack may include one or multiple housing parts. The housing includes at least one housing part, which is designed as an exterior housing part. The exterior housing part in this case delimits the rechargeable battery pack to the outside and may be touched by a user. In addition, the housing may include at least one internal housing part, which is fully enclosed by the at least one housing part. The housing of the rechargeable battery pack includes, in particular, a cell holder for accommodating the rechargeable battery cells, the individual cell receptacles being assigned to the cell holder. The cell holder is designed preferably as one of the housing parts, the cell holder being capable of being designed as an exterior housing part and/or as an interior housing part. The housing of the rechargeable battery pack may include one or multiple cell holders. The housing parts are connected to one another in a force-fitting, form-fitting and/or materially bonding manner.

According to an example embodiment of the present invention, the cell holder is formed preferably from a synthetic material, in particular from a thermoplastic synthetic material. The cell holder is formed preferably from a temperature-resistant synthetic material, preferably from a fiber-reinforced synthetic material. The cell holder is formed, in particular, as one part or as one piece. One piece is understood within the context of the present application to mean, in particular, a component, which is formed from one piece and not from multiple components that are connected to one another in a materially bonding and/or force-fitting and/or form-fitting manner. Accordingly, a one-piece component is made of one single material. One part is understood within the context of this application to mean multiple components, which are connected to one another in a materially bonding manner, for example, via 2K injection molding or a material bond. A one-part component may thus be made of one or of multiple materials. Alternatively, it is also possible that the cell holder has a multipart design, the different parts being connected to one another in a force-fitting and/or form-fitting manner. The rechargeable battery pack may include one or multiple cell holders, which are situated next to one another and/or behind one another.

According to an example embodiment of the present invention, the rechargeable battery pack is connectable via a mechanical interface to the consumer in a force-fitting and/or form-fitting manner. The mechanical interface preferably includes at least one actuating element, via which the connection of the rechargeable battery pack to the consumer and/or to the charging device is detachable. The actuating element may, for example, be designed as a lock, a knob, a lever or push button. The actuating element may be situated on the rechargeable battery pack or on the consumer.

In addition, the rechargeable battery pack includes at least one electrical interface, via which the rechargeable battery pack is electrically connectable to the consumer and/or to the charging device. The rechargeable battery pack may, for example, be charged and/or discharged via the electrical connection.

Alternatively or in addition, it is also possible that pieces of information from the rechargeable battery pack to the consumer and vice versa are conveyable via the electrical interface. The electrical interface is designed preferably as a contact interface, in which the electrical connection takes place via a physical contact of at least two conductive components. The electrical interface includes preferably at least two electrical contact elements. One of the electrical contact elements is, in particular, designed as a plus contact and the other electrical contact element is designed as a minus contact. In addition, the electrical interface may include at least one additional contact, which is designed to transfer additional pieces of information to the consumer and/or to the charging device. The additional contacts may be designed as signal contacts, coding contacts, temperature contacts, bus contacts, etc. The electrical contact elements may, for example, be designed as resilient contact elements in the form of contact tulips or as flat contacts in the form of contact blades. Alternatively or in addition, the electrical interface may include a secondary charging coil element for inductive charging.

In addition, according to an example embodiment of the present invention, the rechargeable battery pack preferably includes electronics. The electronics may include, for example, a circuit board, a processing unit, a control unit, a transistor, a capacitor and/or a memory unit. In addition or alternatively, it is also possible that pieces of information are ascertained by the electronics. The electronics are designed for controlling or regulating the rechargeable battery pack and/or the consumer. The electronics include, in particular, a battery management system (BMS), which is designed for monitoring the rechargeable battery pack. The BMS is designed, in particular, to prevent an overcharging and/or a deep discharging of the rechargeable battery pack. The BMS is designed preferably for correct cell balancing. The electronics may also include one or multiple sensor elements, for example, a temperature sensor for ascertaining the temperature within the rechargeable battery pack or a motion sensor for ascertaining motions. The electronics may alternatively or additionally include a coding element such as, for example, a code resistor. The electronic contact elements of the electrical interface of the rechargeable battery pack may be situated on the circuit board of the electronics or may be connected to the circuit board. A circuit board is understood within the context of this application to mean circuit carrier, which includes an organic or inorganic substrate, for example, IMS. The circuit board may be designed as a rigid circuit board or as a flexible circuit board. In addition, the circuit board may be a printed circuit board or a bare circuit board. The circuit board may have a single layer or may have a multilayer design.

According to an example embodiment of the present invention, the cell holder includes at least one rechargeable battery cell receptacle. The rechargeable battery cell receptacle may be designed as an individual cell receptacle for accommodating a single rechargeable battery cell or as a multi-cell receptacle for accommodating multiple rechargeable battery cells. The rechargeable battery cell receptacle is designed, in particular, in such a way that in the state connected to the rechargeable battery cell, a major portion of the outer surface, in particular, a major portion of the lateral surface of the rechargeable battery cell, is enclosed by the rechargeable battery receptacle. At least 60%, preferably at least 70%, preferably at least 90% of the lateral surface of the rechargeable battery, in particular, is enclosed by the rechargeable battery cell receptacle. The rechargeable battery cell receptacle is designed preferably in such a way that the at least one rechargeable battery cell abuts an interior surface of the rechargeable battery cell receptacle and is fixed by the rechargeable battery cell receptacle. The cell holder includes a wall between two rechargeable battery cell receptacles, which insulates the rechargeable battery cell receptacles spatially and electrically and/or thermally from one another.

According to an example embodiment of the present invention, the rechargeable battery cell may be designed as a galvanic cell, which has a structure in which one cell pole is positioned at one end and a further cell pole is positioned at the opposite end. The rechargeable battery cell includes, in particular, a positive cell pole at one end and a negative pole at an opposite end. The rechargeable battery cells are designed preferably as NiCd rechargeable battery cells or NiMh rechargeable battery cells, particularly preferably as lithium-based rechargeable battery cells or lithium-ion rechargeable battery cells. Alternatively, it is also possible, for example, that the rechargeable battery cell is designed as a pouch cell. The rechargeable battery voltage of the rechargeable battery pack is generally a multiple of the voltage of an individual rechargeable battery cell and results from the (parallel or serial) switching of the rechargeable battery cells. Thus, current rechargeable battery cells having a voltage of 3.6 V result in an exemplary rechargeable battery voltage of 3.6 V, 7.2 V, 10.8 V, 14.4 V, 18 V, 36 V, 54V, 108 V, etc. The rechargeable battery cell is designed preferably at least essentially as a cylindrical round cell, the cell poles being situated at ends of the cylindrical shape.

According to an example embodiment of the present invention, the rechargeable battery pack includes, in particular, at least one cell connector, which is designed for electrically connecting the rechargeable battery cells to the electronics, in particular, to the circuit board and/or to the electrical contact elements. The cell connectors may have a one-piece, one-part or multipart design. The cell connectors may be connected to the housing of the rechargeable battery pack, in particular to the cell holder, in a force-fitting and/or form-fitting manner. It is equally possible that the cell connector is partially or fully encapsulated by the housing, in particular, by the cell holder. The cell connector is formed from a metallic material. The cell connector may, for example, be formed from a pure copper (copper content >95%), from a copper alloy or from a nickel compound, from a steel, in particular, hilumin or from an aluminum alloy or aluminum. The cell connectors may be materially bonded at end faces or at the lateral surface of the rechargeable battery cells.

The cell connector includes a cell connection element for electrically connecting the rechargeable battery cells and a circuit board connection element for electrically connecting to the circuit board. The cell connection element in this case abuts directly and immediately the rechargeable battery cell, in particular, a cell pole of the rechargeable battery cell and is preferably materially bonded with the cell pole. The material bond may take place using a soldering method or using a welding method, in particular, using a resistance welding method or using a laser welding method. Alternatively or in addition, a material bond using an ultrasonic welding method is also possible. The weld connection in this context differs from the solder connection, in particular, in that in the case of the weld connection, a partial melting of the components to be connected takes place. The material bond may take place with the aid of a material bonding means. In the case of a soldering method, the material bonding means may be formed as solder or as a solder layer. In the case of a welding method, the material bonding means may, for example, be formed as a metal platelet, which increases the resistance locally. The circuit board connection element may be connected directly to the circuit board, for example, to a contact surface of the circuit board, or indirectly to the circuit board, for example, via an electrical contact element.

The circuit board is designed preferably as a rigid circuit board including an organic substrate. The circuit board includes an upper side and a lower side, the lower side facing the rechargeable battery cells. The circuit board may include one or multiple gaps for the cell connector. The gap is designed in such a way that with the aid of the gap, a passage is formed between the upper side and the lower side. The gap may be situated at the edge of the circuit board or within the circuit board. The gap may thus have a closed or an open edge.

According to an example embodiment of the present invention, the center axes of the individual cell receptacles extend coaxially or in parallel to an accommodation direction, along which the rechargeable battery cells are mounted or inserted in the individual cell receptacles. The diameter of the rechargeable battery cells is subject to a certain production-related tolerance. The individual cell receptacles may be rigidly designed, an inner diameter of the individual cell receptacles being designed to be greater than the diameter of the rechargeable battery cells. Rechargeable battery cells having a tolerance-related larger diameter thus have less clearance in the individual cell receptacles than the rechargeable battery cells having a tolerance-related smaller diameter. The individual cell receptacles may also include a fastening means for the radial fixation of the rechargeable battery cells in the individual cell receptacles. Thus, a clearance-free and stable accommodation may be advantageously implemented. The radial fixation takes place via an application of a radial force on the rechargeable battery cells by the fastening means.

A center axis of the cylindrical rechargeable battery cells in the accommodated state extends essentially coaxially to the center axis of the individual cell receptacles. Due to the manufacturing tolerance, the center axis of the rechargeable battery cells may extend in parallel to and slightly offset from the center axis of the individual cell receptacles.

In addition, it is provided according to an example embodiment of the present invention, that the cell holder includes 2n+3 individual cell receptacles, n≥1, in particular, being 1. As a result, a sufficiently large power supply for the consumer may be advantageously implemented. The rechargeable battery pack, in particular, the cell holder, includes at least two rechargeable battery cells per main plane. The intermediate plane may also include one or multiple rechargeable battery cells.

It is further provided that a distance between the two main planes is designed to be greater than a distance between the center axes of the individual cell receptacles in the respective main planes. The distance of the rechargeable battery cells within a main plane is preferably designed to be the same.

It is also provided that the adjacent main planes have essentially the same distance from the intermediate plane. An optimal weight distribution in the rechargeable battery pack may be advantageously implemented as a result.

In addition, it is provided that the cell holder spans a circuit board accommodation area, which is designed for accommodating the circuit board, the circuit board being situated partially or completely in the circuit board accommodation area. In this way, the circuit board may be situated protected by the cell holder. The cell holder may include a recess for at least one temperature sensor. The temperature sensor may be connected directly on the circuit board or indirectly to the circuit board, for example, via a cable connection or a Flex PCB. The temperature sensor may, for example, be designed as a PTC or as an NTC.

It is further provided that the circuit board is situated in such a way that a circuit board plane spanned by the circuit board is situated in parallel to the main plane. The circuit board is, in particular, situated in such a way that the circuit board plane has a distance from the intermediate plane, which is in a range between 30% and 55%, preferably in a range between 40% and 45%, of the diameter of the rechargeable battery cells.

The present invention also relates to a cell holder for a rechargeable battery pack as previously described.

The present invention relates to a rechargeable battery pack, including a housing, including at least one rechargeable battery cell, including a cell connector and including a circuit board, the at least one rechargeable battery cell being electrically connected to the circuit board via the cell connector. It is provided that the circuit board includes a connection point for the material bonding of the cell connector to the circuit board, the connection point being situated on a side of the circuit board facing away from the rechargeable battery cells. In this way, a secure connection of the cell connector to the circuit board may be advantageously implemented.

The connection point may be provided for a welding method and/or for a soldering method. The connection point includes a contact surface. The contact surface is situated preferably on an outer layer of the circuit board. The contact surface is designed, in particular, as a surface metallization, for example, as a copper pad. The connection point is connected preferably to a conductor track of the circuit board. The connection point may include a material bonding means such as, for example, a soldering pad or a weld platelet.

In addition, it is provided that the rechargeable battery pack includes a mounting aid for mounting support. The mounting aid may be designed as one piece or as one part with the housing, in particular, with the cell holder. The support of the connection of the cell holder to the cell connector takes place during the mounting process or in the connected state.

It is further provided that the circuit board includes a recess, in which the mounting aid and the cell connector are situated, the mounting aid having a length that is designed to be greater than a thickness of the circuit board. The mounting aid includes, in particular, a rounded edge on the side facing away from the connection point, which is provided for flexing the cell connector. As a result, the likelihood of damage to the cell connector during mounting is advantageously reduced.

It is also provided that the rechargeable battery pack includes a support element, on which the circuit board rests in the area of the connection point. The support element is situated preferably on a side of the circuit board facing the rechargeable battery cells. The support element is designed to support the circuit board during the welding process or soldering process, so that the mechanical load of the circuit board is reduced. The support element may be designed as one piece or as one part with the housing, in particular with the cell holder, of the rechargeable battery pack. An air gap, which is closed as a result of a mechanical load of the circuit board in the welding process or soldering process, may also be formed between the support element and the circuit board. The support element may have a rigid or a flexible design. A rigid support element is understood to mean that the support element does not yield under the load during the connection process and does not change its shape. A flexible support element is understood to mean that the support element yields elastically or plastically during the connection process.

In addition, it is provided that the circuit board includes a contact surface, which is connected to a weld platelet via a material bonding means in a materially bonding manner. The material bonding means may be designed, for example, as a solder layer or as an adhesive layer or an adhesive film. The contact surface is assigned to the connection point. The solder layer is provided for connecting the weld platelet to the contact surface in a materially bonding manner. The weld platelet is made of a metallic material. The metallic material is adapted to the material of the cell connector. The weld platelet is designed for connecting the cell connector to the connection point via a welding method in a materially bonding manner.

It is further provided that the cell connector, in particular, a dimple of the cell connector, is directly connected to the weld platelet. In this way, it is advantageously possible to produce an optimal weld connection. The dimple is designed in such a way that the weld platelet comes only partially into contact with the cell connector.

It is also provided that the solder layer and/or the contact surface and/or the weld metal platelet includes a recess. The recess is designed, in particular, in such a way that a cavity is formed between the weld metal platelet and the circuit board. This advantageously reduces the transfer of heat in the area of the recess, as a result of which the circuit board is protected from damage during the welding process. The recesses may be situated adjacent to one another and/or offset from one another. The solder layer and/or the contact surface and/or the weld metal platelet may include one or multiple recesses, in particular, a different number of recesses.

In addition, it is provided that the weld metal platelet includes a dimple, which extends in a direction facing away from the circuit board. The dimple is designed in such a way that a cavity is formed between the weld metal platelet and the circuit board.

It is also provided that the recess is situated in a weld area, in particular, in the area of the dimple. This advantageously reduces the transfer of heat in an area with high temperatures during the welding process.

In addition, it is provided that the solder layer and/or the contact surface include(s) at least one degassing channel for expanding the trapped air. In this way, a safe welding process may be advantageously implemented.

The present invention further relates to a method for welding a cell connector on a circuit board. According to an example embodiment of the present invention, the cell connector is welded via a weld platelet onto a contact surface of the circuit board. It is provided that a cavity is formed in the immediate weld area between the weld platelet and the circuit board. In this way, the heat is advantageously optimally introduced for the materially bonding connection. The direct weld area in this case is the area that is situated in the immediate surroundings of the heat input. In the case of a resistance welding method, the direct weld area is situated in the area of the bearing surface of the weld electrodes and/or in the area of the bearing surface of the dimple. In the case of a laser welding method, the weld area corresponds to the area that is exposed to the laser beam.

In addition, it is provided that the weld platelet is connected to the circuit board via a solder layer and the solder layer and/or the contact surface and/or the weld metal platelet include(s) a recess. The welding takes place preferably via a resistance welding method or a laser welding method.

It is further provided that the recess of the solder layer is produced with the aid of a solder resist.

### BRIEF DESCRIPTION OF THE DRAWINGS

Further advantages result from the following drawing description. The figures and the description contain numerous features in combination. Those skilled in the art will also appropriately consider the features individually and combine them to form meaningful further combinations. Reference numerals of features of different specific embodiments of the present invention, which essentially correspond to one another, are provided with the same number and with a letter characterizing the specific embodiment.

FIG. 1 shows a perspective view of an electric bicycle including a rechargeable battery pack according to an example embodiment of the present invention,

FIG. 2 shows a perspective view of the rechargeable battery pack without the housing, according to an example embodiment of the present invention.

FIG. 3 shows a front view of a cell holder including inserted rechargeable battery cells of the rechargeable battery pack, according to an example embodiment of the present invention.

FIG. 4 shows a section through a connection point of the rechargeable battery pack, according to an example embodiment of the present invention.

FIG. 5A schematically shows a side view of the connection point according to FIG. 4.

FIG. 5B schematically shows a top view of the connection point according to FIG. 4.

FIG. 6A schematically shows a side view of an alternative specific embodiment of a connection point for a rechargeable battery pack.

FIG. 6B schematically shows a top view of the connection point according to FIG. 6A.

### DETAILED DESCRIPTION OF EXAMPLE EMBODIMENTS

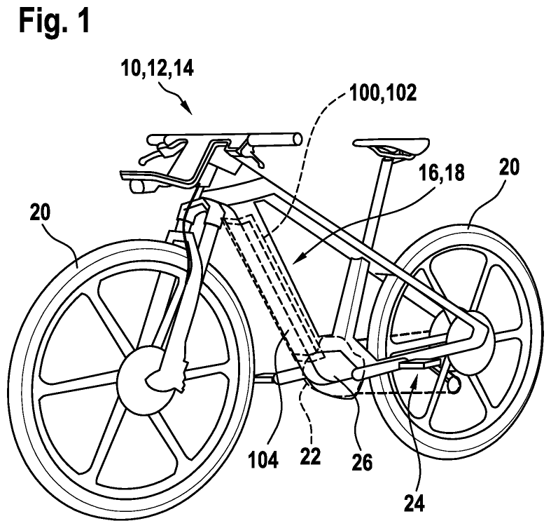

A consumer 10 including a rechargeable battery pack 100 is shown in a schematic side view in FIG. 1. Consumer 10 is designed by way of example as an electrically driven means of transportation 12, in particular, as an electric bicycle 14. Electric bicycle 14 may, for example, be designed as a Pedelec or as an eBike.

Electric bicycle 14 includes a housing 16 in the shape of a frame 18 or of a bicycle frame. Two wheels 20 are connected to frame 18. Consumer 10 also includes a drive unit 22, which includes an electric motor or auxiliary motor. The electric motor is designed preferably as a permanent magnet-excited, brushless DC motor. The electric motor is designed, for example, as a mid-mounted motor, a hub motor or the like also being possible.

Drive unit 22 includes a control unit (not shown), which is designed for controlling or regulating electric bicycle 14, in particular, the electric motor. Electric bicycle 14 includes a pedal crank 24. Pedal crank 24 includes a pedal crankshaft (not shown).

The control unit and drive unit 22 including the electric motor and the pedal crankshaft are situated in a drive housing 26 connected to the frame. The drive motion of the electric motor is preferably transferred via a gear (not shown) to the pedal crankshaft, the amount of assistance by drive unit 22 being controlled or regulated with the aid of the control unit.

Consumer 10 is electrically and mechanically connected to rechargeable battery pack 100, which is designed for supplying power to drive unit 22. Rechargeable battery pack 100 is designed as a removable rechargeable battery pack 102. The underside of frame 18 includes an opening, through which rechargeable battery pack 100 is inserted or pivoted into frame 18. In the connected state, the opening is closed by a housing 104 of rechargeable battery pack 100. Alternatively, it is possible that frame 18 itself closes the opening or the opening is closed by a cover. Alternatively, it is possible that rechargeable battery pack 100 is designed to be detachable at frame 18 or to be attachable at a luggage carrier not shown. Alternatively, rechargeable battery pack 100 may also be inserted from above or laterally. In addition, it is also possible that rechargeable battery pack 100 is inserted from below into a closed frame tube.

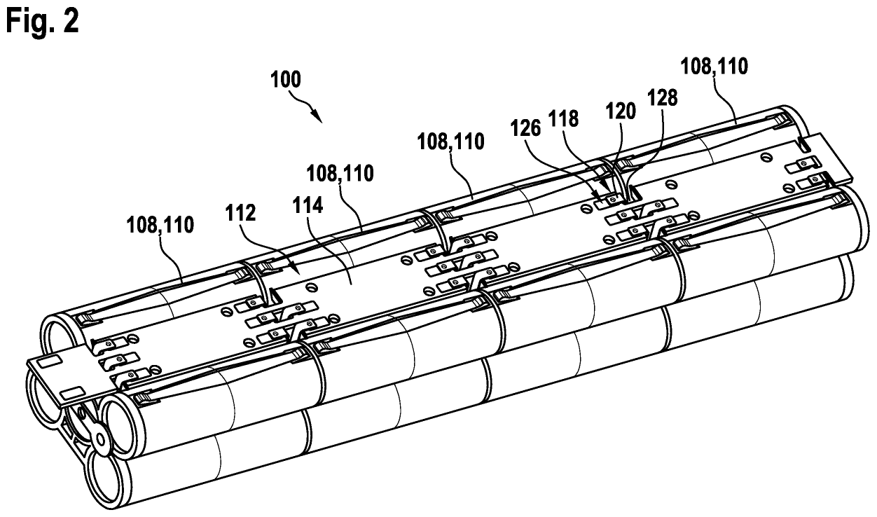

Rechargeable battery pack 100 is shown in a perspective view in FIG. 2 without housing 104 of rechargeable battery pack 100. Housing 104 seals rechargeable battery pack 100 to the outside and is formed of a synthetic material. For detachable connection, rechargeable battery pack 110 includes a mechanical interface not shown, via which rechargeable battery pack 100 is lockable on electric bicycle 14.

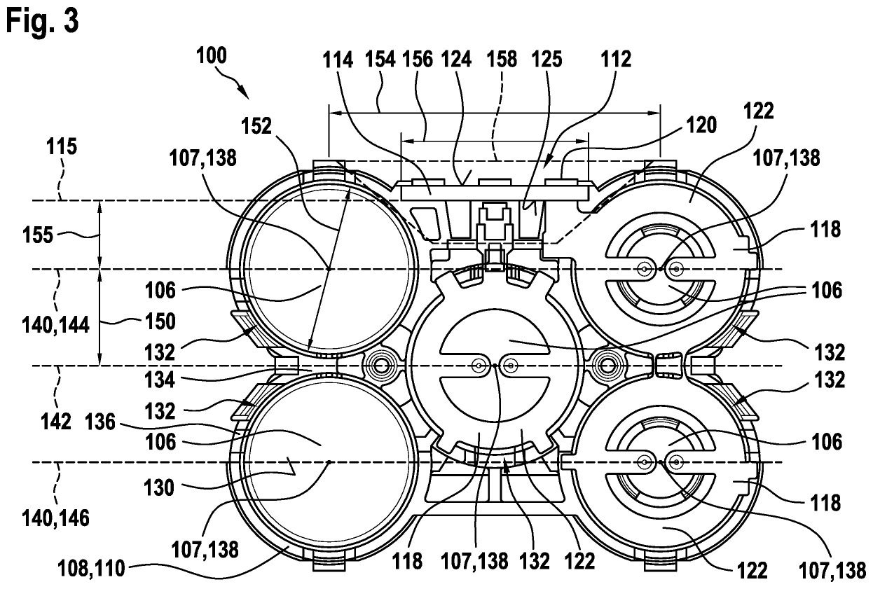

Rechargeable battery pack 100 includes, for example, 20 rechargeable battery cells 106 (see FIG. 3), which are situated in the interior of housing 104. Housing 104 also includes interior housing parts 108 in the form of cell holders 110. Cell holders 110 are designed to accommodate rechargeable battery cells 106. Rechargeable battery pack 100 includes by way of example four cell holders 110, in each of which five rechargeable battery cells 106 are situated. Cell holders 110 have a multi-part design, for example, the parts being connected to one another in a force-fitting and form-fitting manner. It is also possible, however, that cell holders 110 are designed as one part or as one piece. Cell holders 110 are situated behind one another in such a way that rechargeable battery cells 106 accommodated in different cell holders 110 are situated essentially coaxially to one another.

Rechargeable battery cells 106 are designed as cylindrical round cells. Rechargeable battery cells 106 are situated essentially completely in cell holders 110. Cell holders 110 in this case enclose rechargeable battery cells 106 essentially completely along their lateral surface. Rechargeable battery cells 106 have a center axis 107 (see FIG. 3), which corresponds to a center longitudinal axis of rechargeable battery cells 106. Within a cell holder 110, rechargeable battery cells 106 are situated next to one another so that center axes 107 of rechargeable battery cells 106 are situated in parallel to one another.

Rechargeable battery pack 100 includes electronics 112, which are designed for controlling or regulating rechargeable battery pack 100 and/or consumer 10 and/or a charging device not shown. Electronics 112 include by way of example a BMS for monitoring rechargeable battery pack 100.

Electronics 112 include a circuit board 114, which is designed by way of example as a planar and rigid circuit board 114. Circuit board 114 is situated on cell holder 110 and is seated on cell holder 110. Circuit board 114 has a length that corresponds essentially to a length of cell holder 110.

Cell holder 110 and circuit board 114 include connection elements not shown for force-fitting and/or form-fitting connection. Circuit board 114 spans a circuit board plane 115. Circuit board 114 or circuit board plane 115 (see FIG. 3) extends in parallel to rechargeable battery cells 106 or to center axes 107 of rechargeable battery cells 106.

Rechargeable battery pack 100 includes cell connector 118, which is designed for electrically connecting rechargeable battery cells 106 to electronics 112. Cell connectors 118 are designed for providing power and/or for monitoring the individual cell voltage. Cell connector 118 is made of a metallic material, for example, of a steel such as hilumin. In the specific embodiment shown, all cell connectors 118 are connected directly to circuit board 114. Alternatively, it would also be possible that individual cell connectors 118, for example, the cell connector for supplying power, are connected directly to electrical contact elements (not shown) of rechargeable battery pack 100.

Cell connectors 118 are designed by way of example as one piece. Cell connectors 118 include a circuit board connection element 120 for connection to circuit board 114 and a cell connection element 122 (see FIG. 3) for connection to rechargeable battery cells 106.

Circuit board 114 has an upper side 124, which faces away from rechargeable battery cells 106, and a lower side 125, which faces rechargeable battery cells 106. Connection points 126, via which cell connector 118, in particular, circuit board connection element 120, is connected in a materially bonded manner to circuit board 114, for example, via a weld connection, are situated on upper side 124 of circuit board 114. Circuit board 114 has a recess 128, through which cell connectors 118 are guidable to upper side 124 of circuit board 114.

A top view of one of cell holders 110 including inserted rechargeable battery cells 106 is shown in FIG. 3. Two cell connectors 118 are shown by way of example, which are designed for individual cell monitoring and are connected to circuit board 114. Cell connectors 118 are also designed to connect rechargeable battery cells 106 serially and/or in parallel to one another. Cell connectors 118 are connected to rechargeable battery cells 106, in particular, to respective cell poles 130 of rechargeable battery cells 106, via cell connection element 122 with the aid of a resistance welding connection. Thus, cell connection elements 122 extend essentially in parallel to cell poles 130 of rechargeable battery cells 106. Cell poles 130 of rechargeable battery cells 106 are situated essentially perpendicular to circuit board plane 115.

Cell holder 110 includes one individual cell receptacle 132 per rechargeable battery cell 106. Individual cell receptacles 132 include a cylindrical wall 134, which encloses rechargeable battery cells 106 along their lateral surface. Wall 134 is designed in such a way that it is assigned to two different individual cell receptacles 132 between two adjacent rechargeable battery cells 106. Wall 134 is rigid and is formed, for example, from a hard plastic. For play-free fastening of rechargeable battery cells 106, individual cell receptacles 132 include fastening means (i.e., fastener) 136 for radially fixing rechargeable battery cells 106 in individual cell receptacles 132. Fastening means 136 are designed, for example, as resilient latch arms, which apply a force to the lateral surface of rechargeable battery cells 106 in the connected state. Fastening means 136 and cylindrical wall 134 are designed by way of example as one piece with cell holder 110.

Individual cell receptacles 132 each have a center axis 138, which corresponds essentially to center axis 107 of rechargeable battery cells 106. In this case, center axis 107 of rechargeable battery cells 106 may have a slight offset from the center axis of individual cell receptacles 132 as a function of the size of the cell.

The geometry of rechargeable battery pack 100 is determined largely by the arrangement of individual cell receptacles 132 to one another. A compact and flexible rechargeable battery pack 100 installable in consumer 10 may be provided as a result of the design of cell holder 110 described below.

Rechargeable battery cells 106 are distributed on two main planes 140 and on one intermediate plane 142, which are situated in parallel to one another. Cell holder 110 includes two individual cell receptacles 132, which are situated in first main plane 144, and two individual cell receptacles 132, which are situated in second main plane 146. Main planes 140 each include more individual cell receptacles 132 than intermediate plane 142. Situated between main planes 140 is intermediate plane 142, in which a single individual cell receptacle 132 is situated. Main planes 140 and intermediate planes 142 each extend through center axes 138 of individual cell receptacles 132, to which they are assigned.

Individual cell receptacles 132 are situated in such a way that a distance 150 between first or second main planes 144, 146 and intermediate plane 142 is in a range between 54% and 60% of a diameter 152 of rechargeable battery cells 106. Diameter 152 of rechargeable battery cells 106 in this case corresponds essentially to a diameter of individual cell receptacles 132. Distance 150 between first main plane 144 and intermediate plane 142 and distance 150 between second main plane 146 and intermediate plane 142 are, for example, essentially the same.

Circuit board 114 of rechargeable battery pack 100 is situated essentially in parallel to main planes 140. Distance 154 of two adjacent center axes 138 of individual cell receptacles 132 within a main plane 140 is designed to be greater in this case than a width 156 of circuit board 114, in particular, by more than 75% greater than width 156 of circuit board 114. Distance 154 of rechargeable battery cells 106 in main planes 140 is designed, for example, to be the same. It would, however, also be possible that different main planes have different distances between their assigned individual cell receptacles.

Cell holder 110 spans a circuit board accommodation area 158, which is designed for accommodating circuit board 114, circuit board 114 being situated completely in circuit board accommodation area 158. Circuit board accommodation area 158 is situated above individual cell receptacle 132 of intermediate plane 142 and between the two individual cell receptacles 132 of first main plane 144. As a result, the circuit board is situated in such a way that circuit board plane 115 has a distance 159 from first main plane 144, which is in a range between 30% and 55% of diameter 152 of rechargeable battery cells 106 or of individual cell receptacles 132, as a result of which rechargeable battery pack 100 is particularly compactly designed.

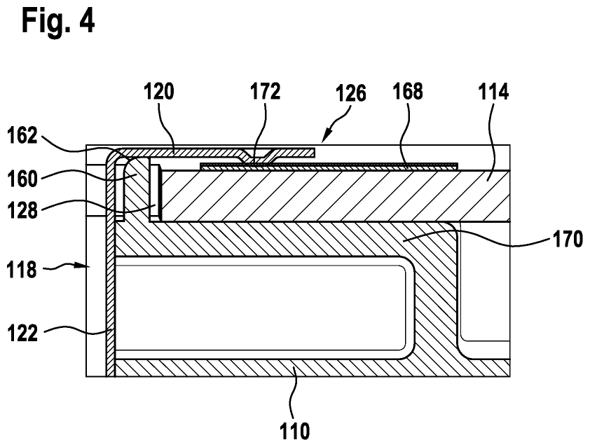

A section through a connection point 126 is shown in FIG. 4, via which cell connector 118 is connected to circuit board 114.

Prior to mounting, cell connector 118 extends essentially completely in one plane. Circuit board connection element 120 thus extends prior to mounting as an extension in a straight line starting from cell connection element 122 in the direction of circuit board 114.

Since connection point 126 is situated on a side facing away from rechargeable battery cells 106, cell connector 110, in particular, circuit board connection element 120, is fed through recess 128 of circuit board 114, so that circuit board connection element 120 protrudes on the upper side of circuit board 114.

Cell holder 110 includes a mounting aid 160, which is situated in recess 128 of circuit board 114. Mounting aid 160 has a length, which is greater than a thickness of circuit board 114, so that mounting aid 160 protrudes on the upper side of circuit board 114. Mounting aid 160 has a rounded edge 162, which is situated on a side facing away from connection point 126. Cell connector 118 is also situated on the side of mounting aid 160, which faces away from connection point 126.

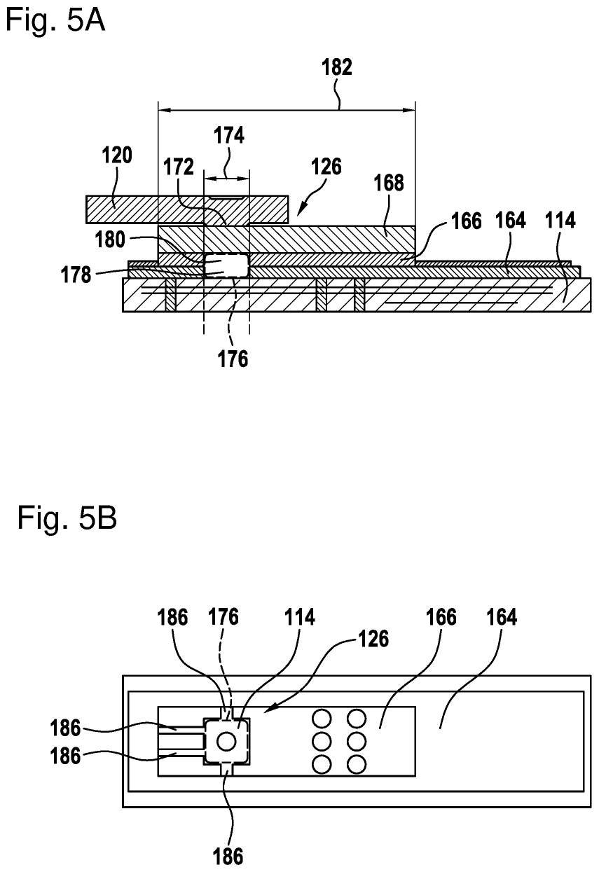

For better illustration, connection 126 is shown in a schematic side view and in a schematic top view in FIG. 5A and in FIG. 5B.

Connection point 126 includes a contact surface 164. Contact surface 164 is designed by way of example as a copper pad on the outer layer of circuit board 114. Contact surface 164 is connected via a solder layer 166 to a weld platelet 168 with the aid of a solder connection. Weld platelet 168 is made of a metallic material. For example, weld platelet 168 is made of the same material as cell connector 118. It is, however, also possible that weld platelet 168 is made of another material.

Weld platelet 168 extends in parallel to circuit board plane 115 (see FIG. 3). To connect cell connector 118 to connection point 126 of circuit board 114, in particular, to connect circuit board connection element 120 to weld platelet 168, circuit board connection element 120 is flexed in the area of rounded edge 162 of mounting aid 160 around the latter and guided above connection point 126. Mounting aid 160 ends approximately at the height of weld platelet 168, so that circuit board connection element 120 in the mounted state rests on mounting aid 160 and on weld platelet 168.

The connection of circuit board connection element 120 to weld platelet 168 takes place via a resistance welding method. For this purpose, circuit board connection element 120 is brought into contact with weld platelet 168. The resistance welding takes place via two electrodes, between which a voltage is applied. In the specific embodiment shown, one electrode is placed on cell connector 118 above connection point 126 and the second electrode is placed directly on weld platelet 168.

Alternatively, it would also be possible that cell connector 118 includes two circuit board connection elements 120, which extend via a gap separately and in parallel to one another, and in each case an electrode is placed on a circuit board connection element 120 in such a way that the gap is situated between the electrodes.

Since the connection also takes place by application of force on circuit board 114 in the area of connection point 126, rechargeable battery pack 100 includes, in particular, cell holder 110, a support element 170, on which circuit board 114 rests in the area of connection point 126 and is supported thereby. Thus, support element 170 is designed both as a mounting stop for aligning circuit board 114 and as a counter bearing during the welding process. Mounting aid 160 and support element 170 are designed by way of example as one piece with cell holder 110.

Cell connector 118, in particular, circuit board connection element 120, includes a dimple 172, via which the bearing surface of cell connector 118 [that bears] on weld platelet 168 is reduced. Dimple 172 of cell connector 118 in this case extends in the direction of circuit board 114. The energy or heat required for welding is introduced essentially in the area of dimple 172. This area thus corresponds to a direct weld area 174.

Connection point 126 includes a cavity 176 in direct weld area 174, which is designed to locally reduce the heat transfer during the welding process. Cavity 176 is formed between weld platelet 168 and circuit board 114.

Cavity 176 is formed in the specific embodiment shown by a recess 178 in contact surface 164 and a recess 180 in solder layer 166. Recesses 178, 180 have, by way of example, the same cross section, but it is also possible that recesses 178, 180 have different cross sections and thus different sizes. Recesses 178, 180, for example, have a rectangular cross section, however, other shapes such as, for example, square, round, triangular, polygonal, etc. are also possible.

An overheating in direct weld area 174 is thus prevented by cavity 176 and the heat is better distributed over entire weld area 182.

For the expansion of trapped air, circuit board 114 also includes degassing channels 186, which are designed by way of example as recesses in solder layer 166 and in contact surface 164.

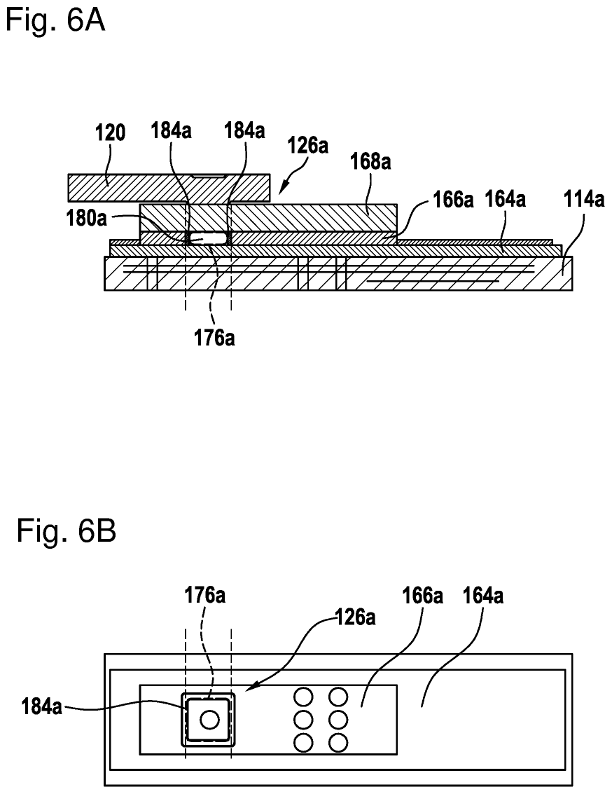

An alternative specific embodiment of connection point 126 according to FIG. 4 is shown in FIG. 6A and FIG. 6B. Connection point 126a in this case differs, in particular, in that cavity 176a is situated only in solder layer 166a in the form of a recess 180a. Thus, cavity 176a is situated between weld platelet 168a and contact surface 164a. This cavity 176a is producible, for example, by inserting solder resist webs 184a, which delimit or form recess 180a.

1-15. (canceled)

16. A rechargeable battery pack, comprising:
a housing;
at least one rechargeable battery cell;
a cell connector; and
a circuit board, the at least one rechargeable battery cell being electrically connected to the circuit board via the cell connector, wherein the circuit board includes a connection point for a materially bonded connection of the cell connector to the circuit board, the connection point being situated on a side of the circuit board facing away from the rechargeable battery cells.

17. The rechargeable battery pack as recited in claim 16, wherein the rechargeable battery pack includes a mounting aid for mounting support.

18. The rechargeable battery pack as recited in claim 17, wherein the circuit board includes a recess, in which the mounting aid and the cell connector are situated, the mounting aid having a length that is greater than a thickness of the circuit board.

19. The rechargeable battery pack as recited in claim 17, wherein the mounting aid has a rounded edge on a side facing away from the connection point, which is provided for flexing the cell connector.

20. The rechargeable battery pack as recited in claim 16, wherein the rechargeable battery pack includes a support element, on which the circuit board rests in an area of the connection point.

21. The rechargeable battery pack as recited in claim 16, wherein the circuit board includes a contact surface, which is connected via a material bonding, via a solder layer, to a weld platelet in a materially bonded manner.

22. The rechargeable battery pack as recited in claim 21, wherein a dimple of the cell connector, is connected directly to the weld platelet.

23. The rechargeable battery pack as recited in claim 21, wherein the material bonding and/or the contact surface and/or the weld metal plate, includes a recess.

24. The rechargeable battery pack as recited in claim 21, wherein the weld metal platelet includes a dimple, which extends in a direction facing away from the circuit board.

25. The rechargeable battery pack as recited in claim 24, wherein the recess is situated in a weld area in an area of the dimple.

26. The rechargeable battery pack as recited in claim 21, wherein the material bonding and/or the contact surface includes at least one degassing channel for an expansion of trapped air.

27. A method for welding a cell connector on a circuit board, the method comprising:
welding the cell connector via a weld platelet, onto a contact surface of the circuit board;
wherein a cavity is situated in a direct weld area between the weld platelet and the circuit board.

28. The method as recited in claim 27, wherein the weld platelet is connected via a solder layer, to the circuit board and the solder layer and/or the contact surface and/or the weld metal platelet includes a recess.

29. The method as recited in claim 27, wherein the welding takes place via a resistance welding method or a laser welding method.

30. The method as recited in claim 27, wherein the contact surface is a metallization in an outer layer of the circuit board.
